(19) United States
(12) Patent Application Publication
(10) Pub. No.: US 2019/0119814 A1
(43) Pub. Date: Apr. 25, 2019

(54) LIQUID PRECURSOR SYSTEM

(71) Applicant: Applied Materials, Inc., Santa Clara, CA (US)

(72) Inventors: Zhiyuan YE, San Jose, CA (US); Garry KWONG, San Jose, CA (US); Errol Antonio C. SANCHEZ, Tracy, CA (US); Nyi O. MYO, San Jose, CA (US)

(21) Appl. No.: 16/161,354

(22) Filed: Oct. 16, 2018

Related U.S. Application Data
(60) Provisional application No. 62/575,953, filed on Oct. 23, 2017.

(51) Int. Cl. C23C 16/455; C23C 16/448

(52) U.S. Cl. CPC C23C 16/45557; C23C 16/448

(57) ABSTRACT

Embodiments of a precursor feed system for a semiconductor process are described herein. The precursor feed system provides improved flow control of a vaporized precursor material to a process chamber by improving flow characteristics of vaporized precursor materials, carried by a carrier gas, which may be an inert gas. The precursor feed system also reduces an occurrence of a pressure drop in conduits that deliver the precursor to the process chamber. Reducing the occurrence of the pressure drop also reduces a decrease of energy from the gas, thus reducing a tendency of the gas to condense in the along the flow path.

### CROSS-REFERENCE TO RELATED APPLICATIONS

This application claims benefit of U.S. Provisional Patent Application 62/575,953 filed on Oct. 23, 2017, which is herein incorporated by reference.

### BACKGROUND

### Field

Embodiments of the present disclosure generally relate to semiconductor manufacturing equipment. More specifically, this disclosure relates to a precursor liquid vaporization and flow system.

### Description of the Related Art

Semiconductor device manufacturing depends heavily on vapor phase reactions and processes such as deposition, etching, and film growth. A precursor vapor is commonly routed to a process chamber where the precursor reacts with other precursors and with a substrate to perform a material deposition process on the substrate. In some cases, the precursor is a liquid at ambient conditions. In that case, the precursor is converted to a vapor to be flowed to the process chamber. For such precursors, a liquid bubbler may be used in which a carrier gas is flowed through the liquid precursor material to vaporize some of the precursor material. A gas mixture including the vaporized precursor and the carrier gas is then provided to the process chamber.

The liquid precursor material is typically held, or stored, in an ampoule for flowing the carrier gas through the precursor material. The carrier gas flows through a tube or pipe into the ampoule at a location below the top surface of the liquid precursor so the carrier gas bubbles through the liquid precursor. As the gas bubbles through the liquid precursor, a portion of the liquid precursor is vaporized into the carrier gas, which exits the ampoule as a mixture of the carrier gas and the vaporized precursor. The liquid precursor may be heated to promote vaporization.

Conventional systems for vaporizing a liquid (or solid) precursor for use in a semiconductor process flow reactive gases with inert gases at moderate pressures to a process chamber that may operate at high vacuum. The gases typically flow through tubing, and may be subjected to flow control using control valves. A back pressure regulator may be used to maintain pressure in the liquid ampoule. As the gas flows through the back pressure regulator, the pressure of the gas (inert plus reactive) drops, and the temperature may also drop as a result of adiabatic expansion. Subsequent flow through the tubing to the chamber may reduce the temperature of the gas due to heat loss. As a result of adiabatic expansion and/or heat loss, some condensation may occur in the tubing. Such condensation can confuse mass flow controllers typically used to control gas flow to the process chamber. Additionally, condensation can render operation of control valves difficult.

As device geometries continue to shrink in the semiconductor industry, manufacturers search for ways to increase process uniformity by reducing variability in all aspects of the manufacturing process, including condensation of the precursor vapor. Thus, there is a need for improvement in delivery of vaporized precursors to semiconductor process chambers.

### SUMMARY

In one embodiment, a system is provided which includes a vessel for vaporizing a precursor and an effluent conduit coupled to the vessel. A back pressure regulator is coupled to the effluent conduit and is downstream of the vessel. A precursor feed line is fluidly coupled to the effluent conduit between the vessel and the back pressure regulator. A plurality of flow controllers is coupled to the precursor feed line. A respective process chamber is coupled to each flow controller of the plurality of flow controllers opposite the precursor feed line.

In another embodiment, a system is provided which includes a vessel for vaporizing a precursor. An effluent conduit having a branch point is coupled to the vessel. A back pressure regulator is coupled to the branch point of the effluent conduit. The back pressure regulator is downstream of the vessel. A precursor feed line is fluidly coupled to the branch point of the effluent conduit. The branch point is disposed downstream of the vessel and upstream of the back pressure regulator. A plurality of branch conduits is coupled to the precursor feed line. A respective flow controller is coupled to each branch conduit of the plurality of branch conduits. Each process chamber of a plurality of process chambers is coupled to the respective flow controllers via a process chamber conduit opposite the branch conduits.

In another embodiment, a system is provided which includes a vessel for vaporizing a precursor. An effluent conduit having a branch point is coupled to the vessel. A push gas conduit is coupled to the effluent conduit. A back pressure regulator is coupled to the effluent conduit downstream of the vessel. A precursor feed line is fluidly coupled to the effluent conduit between the vessel and the back pressure regulator. A plurality of flow controllers coupled to the precursor feed line. A respective process chamber is coupled to each flow controller of the plurality of flow controllers opposite the precursor feed line. A flow path of the vaporized precursor is equidistant from the vessel to each process chamber of the respective process chambers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic flow diagram of a precursor feed system according to one embodiment.

### DETAILED DESCRIPTION

Embodiments of a precursor feed system for a semiconductor process are described herein. The precursor feed system provides improved flow control of a vaporized precursor material to a process chamber by improving flow characteristics of vaporized precursor materials, carried by a carrier gas, which may be an inert gas. The precursor feed system also reduces an occurrence of a pressure drop in conduits that deliver the precursor to the process chamber. Reducing the occurrence of the pressure drop also reduces a decrease of energy from the gas, thus reducing a tendency of the gas to condense along the flow path.

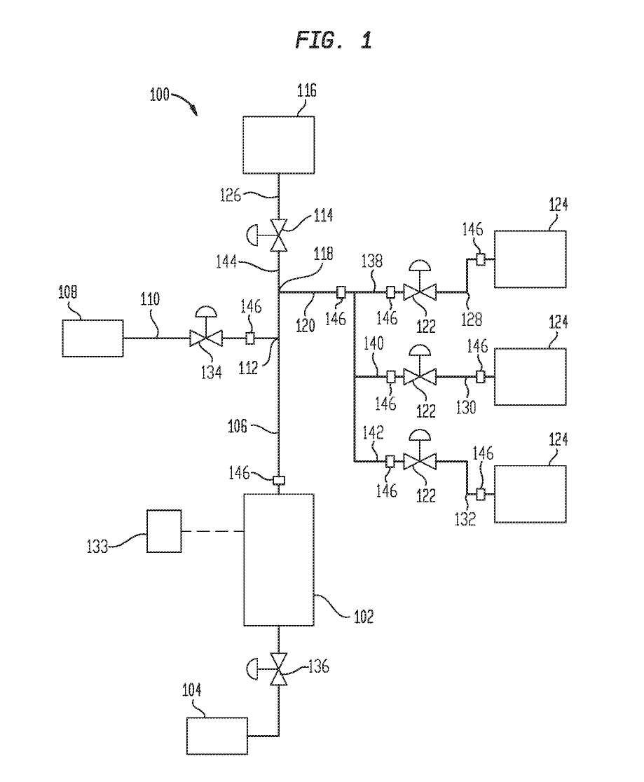

FIG. 1 is a schematic flow diagram of a precursor feed system 100 according to one embodiment. The precursor feed system 100 includes a precursor vaporization vessel 102 and a carrier gas source 104 fluidly coupled to the precursor vaporization vessel 102. Carrier gas from the carrier gas source 104 flows through the precursor vaporization vessel 102 helping to vaporize a precursor held therein. In one embodiment, a valve 136 is disposed between the carrier gas source 104 and the precursor vaporization vessel 102 to control a flow of the carrier gas entering the precursor vaporization vessel 102. The precursor may be a liquid or a solid. The precursor vaporization vessel 102 is configured to vaporize the precursor when the carrier gas from the carrier gas source 104 flows therethrough. For example, an energy application structure (not shown) may be disposed within the precursor vaporization vessel 102 or therearound, such as an internal heat exchanger or an external heat jacket. In another example, the carrier gas may be used to apply energy to the precursor in a particular way within the precursor vaporization vessel 102.

The carrier gas mixes with vaporized precursor within the precursor vaporization vessel 102 and exits the precursor vaporization vessel 102 as a gas mixture through an effluent conduit 106. The effluent conduit 106 is in fluid communication with the precursor vaporization vessel 102. A push gas source 108 is in fluid communication with the effluent conduit 106 via a push gas conduit 110. The push gas conduit 110 is coupled to the effluent conduit 106 at a push gas mixing point 112 downstream of the precursor vaporization vessel 102. The push gas source 108 provides a push gas to the precursor feed system 100. The push gas dilutes a concentration of the precursor gas in the gas mixture. The push gas also increases a pressure of the gas mixture in the precursor feed system 100. In one embodiment, a valve 134 is disposed on the push gas conduit 110 between the push gas source 108 and the effluent conduit 106. The valve 134 controls a flow of the push gas entering the precursor feed system 100 from the push gas source 108. Injection of the push gas at the push gas mixing point 112 mitigates or reduces the condensation of material within conduits of the precursor feed system 100.

A gas mixture is formed at the push gas mixing point 112 which includes the vaporized precursor, the carrier gas, and the push gas. The gas mixture flows toward a branch point 118 (located downstream of the push gas mixing point 112) of the precursor feed system 100. The branch point 118 is disposed between the push gas mixing point 112 and a back pressure regulator 114. The push gas mixing point 112 is downstream of the precursor vaporization vessel 102 and upstream of the branch point 118.

The back pressure regulator 114 is coupled to the branch point 118 via a conduit 144. The back pressure regulator 114 is in fluid communication with a vessel 116 via a reduced pressure conduit 126. The back pressure regulator 114 is disposed between the vessel 116 and the branch point 118. A process feed line 120 is coupled to the branch point 118. In one embodiment, the vessel 116 is a storage vessel for at least a portion of the gas mixture that does not flow into the process feed line 120. In other embodiments, the vessel 116 is an overflow vessel, an abatement chamber, a process chamber, or scrubber, or a recycler. In one embodiment, the vessel 116 is not flow or pressure dependent.

As the gas mixture enters the effluent conduit 106 from the precursor vaporization vessel 102, a pressure in the precursor feed system 100 increases. When the pressure in the precursor feed system 100 increases to more than a pressure value set by the back pressure regulator 114, the back pressure regulator 114, which is not in the flow path of the gas mixture to the process chamber 124, opens to enable at least a portion of the gas mixture to flow to the vessel 116. When the pressure in the precursor feed system 100 is reduced to the pressure value set by the back pressure regulator 114, the back pressure regulator 114 closes to maintain the pressure in the precursor feed system 100. The back pressure regulator 114 regulates flow of the gas mixture in the precursor feed system 100 to maintain the pressure in the precursor vaporization vessel 102 and the precursor feed system 100. Maintaining the pressure in the precursor feed system 100 prevents the vaporized precursor from condensing along the flow path of the gas mixture.

The process feed line 120 may divide into a plurality of branch conduits 138, 140, and 142. A flow controller 122, such as a mass flow controller, is disposed on each of the plurality of branch conduits 138, 140, and 142. Each flow controller 122 controls a flow of the gas mixture to a respective process chamber 124. The flow controllers 122 are arranged in parallel to one another. In one embodiment, one or more of the flow controllers 122 are in series with at least one other flow controller 122. In that case, the flow controller 122 closest to the branch point 118 controls flow of the gas mixture to any flow controllers 122 and process chambers 124 that are downstream.

The process chambers 124 are in fluid communication with a respective flow controller 122 via a corresponding process chamber conduit 128, 130, and 132. In one embodiment, a flow path of the gas mixture from the branch point 118 to the process chambers 124 is equidistant. In one embodiment, the flow paths from the branch point 118 to the process chambers 124 are different. In one example, a length of the plurality of branch conduits 138, 140, 142 are the same while a length of the process chamber conduits 128, 130, 132 are different. In another example, the length of the process chamber conduits 128, 130, 132 are the same while the length of the branch conduits 138, 140, 142 are different. Each of the flow controllers 122 and the process chambers 124 are downstream of the branch point 118.

A controller 133 is coupled to the precursor feed system 100. The controller 133 controls a rate of vaporization of the precursor in the precursor vaporization vessel 102. While the controller 133 is shown coupled to the precursor vaporization vessel 102, it is to be understood that the controller 133 is coupled to the precursor feed system 100, generally, and is configured to control aspects of the each of the valves 134, 136, the flow controllers 122, and the back pressure regulator 114 to control a flow of a fluid therethrough. In one embodiment, the controller 133 is coupled to the push gas source 108 to control flow of the push gas therefrom. Other aspects of the precursor feed system 100 may also be controlled by the controller 133.

The precursor feed system 100 reduces an occurrence of condensation of the vaporized precursor in the process feed line 120 and the branch conduits 138, 140, and 142. For example, an occurrence of condensation between the process feed line 120 and the flow controllers 122 or between the flow controllers 122 and the corresponding process chambers 124 may be reduced. The back pressure regulator 114 is not in the flow path of precursor gas mixture from the precursor vaporization vessel 102 to the process chambers 124. That is, the precursor gas mixture flows from the precursor vaporization vessel 102 directly to the flow controllers 122 and is not subjected to a pressure drop through the back pressure regulator 114, unless the back pressure regulator 114 is in an open state, as instructed by the controller 133. Thus, an enthalpy of the gas mixture is not driven to a condensation point as readily.

The precursor feed system 100, from the precursor vaporization vessel 102 to the flow controllers 122, operates at the pressure set by the back pressure regulator 114 and the push gas source 108. In addition, because the flow controllers 122 create the majority of the pressure drop between the precursor vaporization vessel 102 and the process chambers 124 (for example, when opening to allow flow therethrough), the flow controllers 122 operate at more manageable pressure drop rather than trying to control a fast flowing gas stream using very little pressure drop. This enables easier tuning and better response of the flow controllers 122, enabling a more uniform flow of the gas mixture to the process chambers 124. While the precursor feed system 100 as illustrated in FIG. 1 includes three flow controllers 122, it is contemplated that there may be other valves, such as block valves, and other flow features in the precursor feed system 100.

While three process chambers 124 are illustrated in FIG. 1, any number of process chambers 124, such as one, two, or any suitable number, may be coupled to the precursor feed system 100. As illustrated, a single precursor vaporization vessel 102 may be used to provide process gas to multiple process chambers 124. In this way, variability associated with operation of the precursor vaporization vessel 102, such as heat input rates, pressure and temperature measurement and control, carrier gas flow control, precursor gas concentration, and the like, is removed because the components of the precursor feed system 100 are common from the precursor vaporization vessel 102 to the back pressure regulator 114. In addition, the precursor feed system 100 reduces space requirements and costs compared to conventional feed systems, which typically have dedicated precursor feed hardware for each respective process chamber of a semiconductor fabrication plant. Additionally or alternatively, multiple precursor feed systems 100, including additional precursor vaporization vessels 102 and back pressure regulators 114, may be coupled to the process chambers 124 to provide different precursor mixtures to the process chambers 124.

During operation of the precursor feed system 100, one or more valves of the precursor feed system 100 are opened and/or closed to direct precursor gases to a predetermined process chamber 124 at desired times. The opening and closing of valves results in pressure and/or temperature changes within conduits or tubing of the precursor feed system 100. The changes in temperature or pressure may result in inadvertent condensation of material within the conduits or tubing.

To mitigate or prevent undesired condensation, the valve 134 of the push gas source 108 may be operated to maintain a desired pressure and/or temperature within the conduits/tubing of the precursor feed system 100. Maintenance of temperature/pressure mitigates condensation within the conduits/tubes of the precursor feed system 100. As noted above, the controller 133 facilitates control of the valve 134 of the push gas source 108.

The controller 133 may operate the valve 134 of the push gas source 108 based on signals from sensors 146 disposed along conduits/tubes of the precursor feed system 100. Exemplary sensors 146 may include, for example, temperature and/or pressure sensors. In response to signals received from the sensors 146, the controller 133 may operate aspects of the precursor feed system 100, such as the valve 134 of the push gas source 108 and/or the back pressure regulator 114, to mitigate condensation within the precursor feed system 100. In other embodiment, sensors, such as sensors 146, may be disposed in different locations throughout the precursor feed system 100. In addition, although not shown, it is contemplated that heating elements may be disposed along conduits/tubes of the precursor feed system 100 to further facilitate pressure/temperature regulation. In such an example, the controller 133 is configured to control the heating elements.

The precursor feed system 100 described herein can be used to vaporize many precursor materials for use in semiconductor processes. For example, higher order silanes, such as disilane, trisilane, and other silane oligomers, can be vaporized in the precursor feed system 100. Likewise, higher order germanes and boranes, optionally alkylated, can be used. Mixed molecules of silicon, germanium, carbon, boron, phosphorus, and arsenic can also be vaporized in the precursor feed system 100. Other precursors, such as alkyl arsines and phosphines, for example tertiary butyl arsine (TBA) can be vaporized in the precursor feed system 100. Organometallic precursors such as alkyls of Group III metals, for example trimethyl aluminum, trimethylgallium, and/or trimethylindium can be vaporized in the precursor feed system 100. Mixtures of all of the above precursors can be used in the precursor feed system 100, described herein.

While the foregoing is directed to embodiments of the present disclosure, other and further embodiments of the disclosure may be devised without departing from the basic scope thereof, and the scope thereof is determined by the claims that follow.

1. A system, comprising:
a vessel for vaporizing a precursor;
an effluent conduit coupled to the vessel;
a back pressure regulator coupled to the effluent conduit, the back pressure regulator downstream of the vessel;
a precursor feed line fluidly coupled to the effluent conduit between the vessel and the back pressure regulator;
a plurality of flow controllers coupled to the precursor feed line; and
a respective process chamber coupled to each flow controller of the plurality of flow controllers opposite the precursor feed line.

2. The system of claim 1, further comprising:
a controller coupled to and configured to control a flow of fluid through the vessel, the back pressure regulator, and each flow controller of the plurality of flow controllers.

3. The system of claim 1, wherein the respective process chambers are downstream of the back pressure regulator.

4. The system of claim 1, wherein each flow controller of the plurality of flow controllers is parallel to one another.

5. The system of claim 1, further comprising:
a plurality of process chamber conduits, each process chamber conduit of the plurality of process chamber conduits disposed between a respective flow controller of the plurality of flow controllers and the respective process chamber.

6. The system of claim 5, wherein each flow controller of the plurality of flow controllers is equidistant from the respective process chamber along the plurality of process chamber conduits.

7. The system of claim 6, wherein each flow controller of the plurality of flow controllers is in fluid communication with a branch point on the precursor feed line, and a distance between each flow controller of the plurality of flow controllers and the respective process chamber is different.

8. A system, comprising:
a vessel for vaporizing a precursor;
an effluent conduit having a branch point, the effluent conduit coupled to the vessel;
a back pressure regulator coupled to the branch point of the effluent conduit, the back pressure regulator downstream of the vessel;
a precursor feed line fluidly coupled to the branch point of the effluent conduit, the branch point disposed downstream of the vessel and upstream of the back pressure regulator;
a plurality of branch conduits coupled to the precursor feed line;
a respective flow controller coupled to each branch conduit of the plurality of branch conduits; and
a plurality of process chambers, each process chamber of the plurality of process chambers coupled to the respective flow controllers via a process chamber conduit opposite the branch conduits.

9. The system of claim 8, further comprising:
a controller coupled to and configured to control a flow of fluid through the vessel, the back pressure regulator, and each flow controller of the plurality of flow controllers.

10. The system of claim 8, wherein the respective process chambers are downstream of the flow controllers.

11. The system of claim 8, wherein each flow controller of the plurality of flow controllers is parallel to remaining flow controllers of the plurality of flow controllers.

12. The system of claim 8, further comprising:
a plurality of process chamber conduits, each process chamber conduit of the plurality of process chamber conduits disposed between one flow controller of the plurality of flow controllers and the respective process chamber.

13. The system of claim 12, wherein each flow controller of the plurality of flow controllers is equidistant from the respective process chamber along the plurality of process chamber conduits.

14. The system of claim 13, wherein each flow controller of the plurality of flow controllers is in fluid communication with the branch point, and a distance between each flow controller of the plurality of flow controllers and the respective process chamber is different.

15. A system, comprising:
a vessel for vaporizing a precursor;
an effluent conduit having a branch point, the effluent conduit coupled to the vessel;
a push gas conduit coupled to the effluent conduit;
a back pressure regulator coupled to the effluent conduit, the back pressure regulator downstream of the vessel;
a precursor feed line fluidly coupled to the effluent conduit between the vessel and the back pressure regulator;
a plurality of flow controllers coupled to the precursor feed line; and
a respective process chamber coupled to each flow controller of the plurality of flow controllers opposite the precursor feed line, a flow path of the vaporized precursor equidistant from the vessel to each process chamber of the respective process chambers.

16. The system of claim 15, further comprising:
a reduced pressure conduit coupled to the back pressure regulator opposite the effluent conduit; and
a container coupled to the reduced pressure conduit.

17. The system of claim 15, wherein the back pressure regulator is configured to maintain a pressure in the vessel and the effluent conduit.

18. The system of claim 15, further comprising:
a controller coupled to and configured to control a flow of fluid through the vessel, the back pressure regulator, and each flow controller of the plurality of flow controllers.

19. The system of claim 15, wherein each flow controller of the plurality of flow controllers is parallel to other flow controllers of the plurality of flow controllers.

20. The system of claim 15, wherein the push gas conduit is coupled to the effluent conduit downstream of the vessel and upstream of the branch point, the plurality of flow controllers are downstream of the branch point, and the process chambers are downstream of the flow controllers.
